(19) United States
(12) Patent Application Publication
(10) Pub. No.: US 2006/0289879 A1
(43) Pub. Date: Dec. 28, 2006

(54) Dual-face display apparatus, systems, and methods

(75) Inventors: Ralph M. Mesmer, Banks, OR (US); Achintya K. Bhowmik, Milpitas, CA (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 11/167,243

(22) Filed: Jun. 27, 2005

(51) Int. Cl. H01L 33/00

(52) U.S. Cl. 257/89; 257/E33.006

(57) ABSTRACT

Apparatus and systems, as well as methods and articles, may operate to display image information from one side of a light-emitting material layer disposed between a pair of non-opaque electrodes. The image information may be displayed through a transparent substrate, perhaps adjacent a conductive silicon layer, adjacent one of the electrodes. The image information may also be displayed substantially simultaneously from the other side of the light emitting material layer.

### TECHNICAL FIELD

Various embodiments described herein relate to information displays generally, including apparatus, systems, and methods used to enable the display of information that can be viewed from more than one side or face of a display device.

### BACKGROUND INFORMATION

Some displays are manufactured as light emitting devices (e.g., organic light-emitting diodes (OLEDs)) on opaque silicon wafers. This type of construction permits viewing displayed information from only one side of the display.

### BRIEF DESCRIPTION OF THE DRAWINGS

FIGS. 1A and 1B are block diagrams of apparatus and systems according to various embodiments of the invention.

FIG. 2 is a flow diagram illustrating several methods according to various embodiments of the invention.

FIG. 3 is a block diagram of an article according to various embodiments.

### DETAILED DESCRIPTION

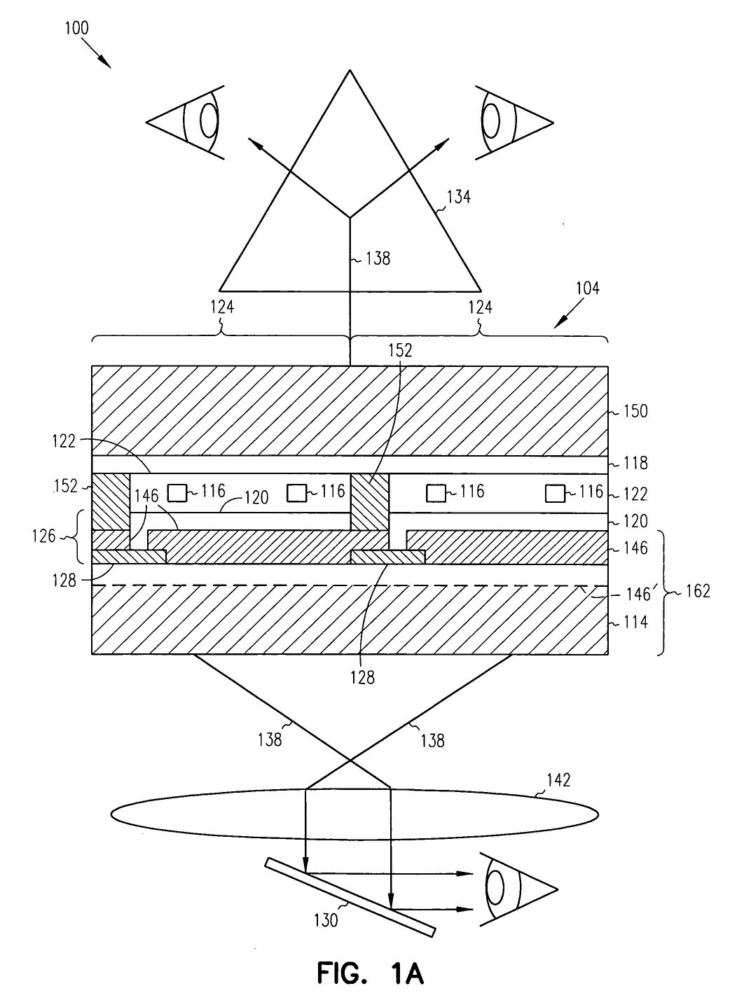

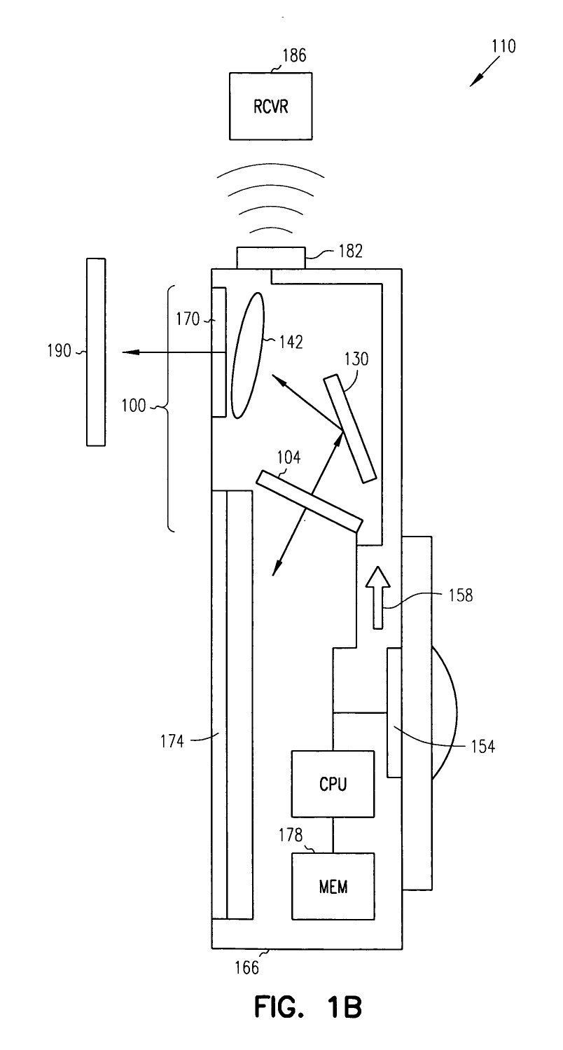

FIGS. 1A and 1B are block diagrams of apparatus 100 and systems 110 according to various embodiments of the invention. The apparatus 100 may include a dual-face display 104, viewable from both sides. One or more mirrors, prisms, and/or lenses may be used to reverse, focus, and project either one or both of the images available from each side of the display 104.

Turning now to FIG. 1A, it can be seen that in some embodiments, the apparatus 100 may include a transparent substrate 114 and a switching component layer 126 adjacent the transparent substrate 114. The transparent substrate 114 may include glass and/or ceramic materials. The non-opaque switching component layer 126 may include may include a layer of crystalline silicon (c-Si) 128, perhaps etched and used to form drive transistors for pixels 124, as well as a non-opaque electrode 120, which may include indium-tin oxide (ITO). In some embodiments, the apparatus 100 may comprise a glass substrate 114 with a 0.1 um layer of c-Si 128 as part of the non-opaque switching component layer 126 bonded to it.

The apparatus 100 may include a light-emitting material layer 122 adjacent the non-opaque switching component layer 126, as well as a non-opaque conductive layer 118 adjacent the light-emitting material layer 122. The light-emitting material layer 122 may include a number of devices, such as one or more light emitting diodes (including OLEDs), lasers, and one or more groups of light emitting devices having one or more colors (e.g., red, blue, yellow or cyan, magenta, yellow). The non-opaque conductive layer 118 may include ITO material, perhaps coated onto the light-emitting material layer 122, or a transparent cover 150.

In some embodiments, the apparatus 100 may include one or more mirrors 130 and/or prisms 134 to reflect image information 138 displayed by the light-emitting material 122. The apparatus may also include one or more lenses 142 to focus the image information 138 displayed by the light-emitting material 122.

Additional layers may be added to the apparatus 100. For example, in some embodiments, the apparatus 100 may include an insulating layer 146 adjacent the non-opaque switching component layer 126. The insulating layer 146 may comprise silicon dioxide (SiO2). The insulating layer 146 may be formed on the transparent substrate 114, and the non-opaque switching component layer 126 may be formed on the insulating layer 146, or vice versa (e.g., the non-opaque switching component layer 126 may be formed on the transparent substrate 114, and then the insulating layer 146 may be formed on the non-opaque switching component layer 126). An additional insulating layer 146′ may be optionally formed on the transparent substrate 114, perhaps prior to forming the non-opaque switching component layer 126 adjacent the transparent substrate 114, so that the non-opaque switching component layer 126 is no longer directly adjacent the transparent substrate 114.

The apparatus 100 may also include a transparent cover 150, perhaps comprising a glass and/or ceramic material, adjacent the non-opaque conductive layer 118. In some embodiments, the apparatus 100 may include a light-absorbing material layer 152, perhaps disposed adjacent the light emitting material layer 122 and used to separate individual pixels 124.

For the purposes of this document, locating one layer “adjacent” another means that the first layer is placed against the second, with none, one, or more intervening layers. Locating one layer “directly adjacent” another means that the first layer is placed against the second, with no intervening layers. In some embodiments, the layers 114, 118, 120, 122, 126, 128, 146, 146′, 150, and 152 may be adjacent each other. In some embodiments, the layers 114, 118, 120, 122, 126, 128, 146, 146′, 150, and 152 may be directly adjacent each other. Thus, everywhere the layers 114, 118, 120, 122, 126, 128, 146, 146′, 150, and 152 are described as adjacent each other herein, they may also be described as directly adjacent each other.

A material that is non-opaque may be translucent or transparent, transmitting greater than 5% of the light that impinges on it. In some embodiments, a non-opaque material may transmit greater than 10%, or greater than 20%, or greater than 30%, or greater than 40%, or greater than 50%, or greater than 60%, or greater than 70%, or greater than 80% of the light that impinges on it. Some layers 114, 118, 120, 122, 126, 146, and 150 may be non-opaque as a whole, but may include opaque materials (e.g., silicon, gold, silver, tin, indium, etc.) used to make components and component connections, such as the c-Si 128 in the switching component layer 126.

Other embodiments may be realized. For example, as seen in FIG. 1B, a system 110 may include one or more apparatus 100, as described above, including one or more dual-face displays 104. The system 110 may also include a light energy to electrical energy conversion device 154 to transmit captured image information 158 to the light-emitting material layer 122 (see FIG. 1A). The light energy to electrical energy conversion device 154 may comprise a charge-coupled device (CCD), similar to or identical to a Sony ICX282AQ frame readout CCD image sensor, or a complementary metal-oxide semiconductor (CMOS) device, similar to or identical to a VLSI Vision Ltd. VV6801 image sensor, among others.

In some embodiments, one or more devices 116, such as a transmissive bottom emitter micro-OLED device, may be formed as a portion of the light-emitting material layer 122 on a c-Si-on-glass (CSOG) substrate 162. One application of the apparatus 100 includes a digital camera 166 that uses the same dual-face display 104 for the viewfinder 170 and the back-of-the-camera monitor 174. The system 110 may also include a memory 178 to store a portion of the captured image information 158, as well as an antenna 182 to transmit a portion of the captured image information 158 to one or more remote receivers 186, perhaps included in a wireless network.

In some embodiments, the system 110 may include one or more mirrors 130 to reflect a portion of the captured image information 158 displayed by the light-emitting material layer 122. The system 110 may also include one or more lenses 142 to project a portion of the captured image information 158 displayed by the light-emitting material layer 122 to a secondary viewing surface 190, such as a projection screen, a wall, a vehicle windshield, or as a portion of a handheld device secondary information display (e.g., the secondary display of a closed clamshell cellular telephone), among others.

Any of the components previously described can be implemented in a number of ways, including simulation via software. Thus, the apparatus 100, dual-face display 104, systems 110, transparent substrate 114, devices 116, non-opaque conductive layer 118, non-opaque electrode 120, light-emitting material layer 122, pixels 124, non-opaque switching component layer 126, c-Si 128, mirrors 130, prisms 134, image information 138, lenses 142, insulating layers 146, 146′, transparent cover 150, light-absorbing material layer 152; light energy to electrical energy conversion device 154, captured image information 158, CSOG substrate 162, digital camera 166, viewfinder 170, back-of-the-camera monitor 174, memory 178, antenna 182, remote receivers 186, and secondary viewing surface 190 may all be characterized as “modules” herein.

Such modules may include hardware circuitry, single and/or multi-processor circuits, memory circuits, software program modules and objects, and/or firmware, and combinations thereof, as desired by the architect of the apparatus 100 and systems 110, and as appropriate for particular implementations of various embodiments. For example, such modules may be included in a system operation simulation package, such as a software electrical signal simulation package, a power usage and distribution simulation package, a capacitance-inductance simulation package, a power/heat dissipation simulation package, a signal transmission-reception simulation package, and/or a combination of software and hardware used to operate, or simulate the operation of various potential embodiments.

It should also be understood that the apparatus and systems of various embodiments can be used in applications other than digital cameras, cellular telephones, heads-up displays, and projectors, and thus, various embodiments are not to be so limited. The illustrations of apparatus 100 and systems 110 are intended to provide a general understanding of the structure of various embodiments, and they are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, single and/or multi-processor modules, single and/or multiple embedded processors, data switches, and application-specific modules, including multilayer, multi-chip modules. Such apparatus and systems may further be included as sub-components within a variety of electronic systems, such as televisions, cellular telephones, personal computers, workstations, radios, video players, vehicles, and others.

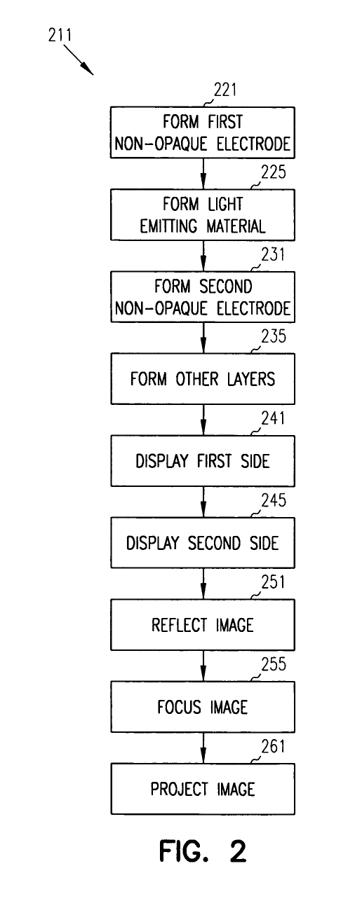

Some embodiments may include a number of methods. For example, FIG. 2 is a flow diagram illustrating several methods 211 according to various embodiments of the invention. A method 211 may include forming a first non-opaque electrode (perhaps as part of a non-opaque switching component layer including c-Si) adjacent a layer of crystalline silicon on a layer of transparent material at block 221, and forming a light-emitting material layer at block 225, perhaps directly on to the first non-opaque electrode. The method 211 may include forming a second non-opaque electrode (e.g., as a non-opaque conductive layer comprising ITO) on the light-emitting material layer, or on a transparent cover, at block 231. Other layers, such as one or more insulating layers (e.g., containing amorphous silicon, including amorphous SiO2) and a transparent cover, may be formed on the non-opaque conductive layer at block 235. Indeed, all of the layers shown in FIG. 1A may be formed in the order described, in a different order, or in any desired order. Given this description of the fabrication process, dual-face displays may now be manufactured on a glass substrate, perhaps making use of some activities similar to or identical to those applied to conventional OLED production.

Thus, in some embodiments, the method 211 may include displaying image information from a first side of the light-emitting material layer disposed between a pair of non-opaque electrodes through a transparent substrate at block 241. The transparent substrate may be located adjacent one of the non-opaque electrodes, which may in turn be disposed adjacent a conductive silicon layer.

The method 211 may include displaying the image information from a second side of the light emitting material layer at block 245. In some embodiments, the method 211 may include displaying the image information as camera viewfinder image information at either of blocks 241 or 245, as well as displaying the image information as a portion of a handheld device primary information display (e.g., the main display of an opened clamshell cellular telephone, or a back-of-the-camera monitor display), and/or displaying the image information on a vehicle windshield.

The method 211 may include reflecting the image information and/or focusing the image information to provide a mirror image at blocks 251 and 255, respectively. In some embodiments, the method 211 may include projecting the image information to a secondary viewing surface at block 261.

It should be noted that the methods described herein do not have to be executed in the order described, or in any particular order. Moreover, various activities described with respect to the methods identified herein can be executed in repetitive, simultaneous, serial, or parallel fashion. Information, including parameters, commands, operands, and other data, can be sent and received in the form of one or more carrier waves.

Upon reading and comprehending the content of this disclosure, one of ordinary skill in the art will understand the manner in which a software program can be launched from a computer-readable medium in a computer-based system to execute the functions defined in the software program. One of ordinary skill in the art will further understand the various programming languages that may be employed to create one or more software programs designed to implement and perform the methods disclosed herein. The programs may be structured in an object-orientated format using an object-oriented language such as Java, Smalltalk, or C++. Alternatively, the programs can be structured in a procedure-orientated format using a procedural language, such as assembly or C. The software components may communicate using any of a number of mechanisms well known to those skilled in the art, such as application program interfaces or interprocess communication techniques, including remote procedure calls. The teachings of various embodiments are not limited to any particular programming language or environment, including Hypertext Markup Language (HTML) and Extensible Markup Language (XML). Thus, other embodiments may be realized.

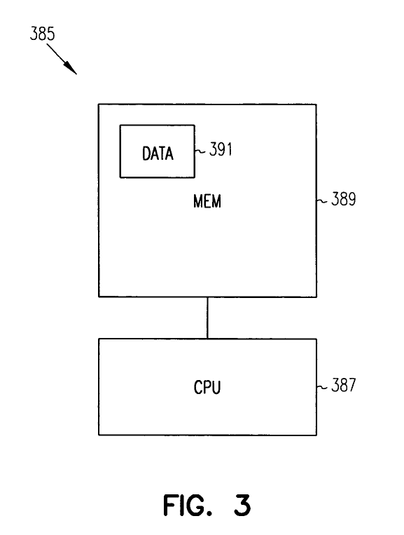

FIG. 3 is a block diagram of an article 385 according to various embodiments, such as a computer, a memory system, a magnetic or optical disk, some other storage device, and/or any type of electronic device or system. The article 385 may include a processor 387 coupled to a machine-accessible medium such as a memory 389 (e.g., a memory including an electrical, optical, or electromagnetic conductor) having associated information 391 (e.g., computer program instructions and/or data), which, when accessed, results in a machine (e.g., the processor 387) performing such actions as displaying image information from the first side of a light-emitting material layer disposed between a pair of non-opaque electrodes through a transparent substrate, where the transparent substrate is adjacent one of the non-opaque electrodes (e.g., adjacent a conductive silicon layer). Additional actions may include displaying the image information from a second side of the light emitting material layer, perhaps as a portion of a handheld device primary information display, or on a vehicle windshield, among others.

Implementing the apparatus, systems, and methods disclosed herein may provide dual-face displays that can be used in a number of applications, including displays that are viewable from both sides (e.g., providing a mirror image on one side). Higher resolution may be possible, such as when the use of c-Si construction permits the implementation of smaller design rules. Reduced manufacturing costs, due to direct manufacture of dual-face devices on glass substrates, may also accrue.

The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. An apparatus, including:
a transparent substrate;
a non-opaque switching component layer adjacent the transparent substrate;
a light-emitting material layer adjacent the non-opaque switching component layer; and
a non-opaque conductive layer adjacent the light-emitting material layer.

2. The apparatus of claim 1, wherein the light-emitting material layer includes:
a light emitting diode.

3. The apparatus of claim 1, wherein the light-emitting material layer includes:
an organic light emitting diode.

4. The apparatus of claim 1, wherein the light-emitting material layer includes:
a group of light emitting devices having at least two colors.

5. The apparatus of claim 1, wherein the transparent substrate includes one of a glass and a ceramic material.

6. The apparatus of claim 1, wherein the non-opaque switching component layer includes crystalline silicon.

7. The apparatus of claim 1, further including:
a mirror to reflect image information displayed by the light-emitting material layer.

8. The apparatus of claim 1, further including:
a lens to focus image information displayed by the light-emitting material layer.

9. The apparatus of claim 1, wherein the non-opaque conductive layer includes:
indium-tin oxide.

10. The apparatus of claim 1, further including:
an insulating layer adjacent the non-opaque switching component layer.

11. The apparatus of claim 10, further including:
a transparent cover adjacent the non-opaque conductive layer.

12. A system, including:
a dual-face display including a transparent substrate, a non-opaque switching component layer adjacent the transparent substrate, a light-emitting material layer adjacent the non-opaque switching component layer, and a non-opaque conductive layer adjacent the light-emitting material layer; and
a light energy to electrical energy conversion device to transmit captured image information to the light-emitting material layer.

13. The system of claim 12, wherein the light energy to electrical energy conversion device comprises one of a charge-coupled device and a complementary metal-oxide semiconductor device.

14. The system of claim 12, further including:
a memory to store a portion of the captured image information.

15. The system of claim 12, further including:
an antenna to transmit a portion of the captured image information to a wireless network.

16. The system of claim 12, further including:
a mirror to reflect a portion of the captured image information displayed by the light-emitting material layer.

17. The system of claim 12, further including:
a lens to project a portion of the captured image information displayed by the light-emitting material layer to a secondary viewing surface.

18. The system of claim 12, wherein the non-opaque switching component layer includes:
crystalline silicon and an electrode.

19. A method, including:
displaying image information from a first side of a light-emitting material layer disposed between a pair of non-opaque electrodes through a transparent substrate adjacent a first one of the non-opaque electrodes adjacent a conductive silicon layer; and
displaying the image information from a second side of the light emitting material layer.

20. The method of claim 19, further including:
displaying the image information as camera viewfinder image information.

21. The method of claim 19, further including:
projecting the image information to a secondary viewing surface.

22. The method of claim 19, further including:
reflecting the image information to provide a mirror image.

23. The method of claim 19, further including:
focusing the image information to provide a mirror image.

24. The method of claim 19, further including:
forming the first one of the non-opaque electrodes as part of a non-opaque switching component layer on the transparent material; and
forming the second one of the non-opaque electrodes as a non-opaque conductive layer of indium-tin oxide on the light-emitting material layer.

25. An article including a machine-accessible medium having associated information, wherein the information, when accessed, results in a machine performing:
displaying image information from a first side of a light-emitting material layer disposed between a pair of non-opaque electrodes through a transparent substrate adjacent a first one of the non-opaque electrodes adjacent a conductive silicon layer; and
displaying the image information from a second side of the light emitting material layer.

26. The article of claim 25, wherein the information, when accessed, results in the machine performing:
displaying the image information as a portion of a handheld device primary information display.

27. The article of claim 25, wherein the information, when accessed, results in the machine performing:
displaying the image information on a vehicle windshield.
